(19) United States
(12) Patent Application Publication
(10) Pub. No.: US 2026/0096028 A1
(43) Pub. Date: Apr. 2, 2026

(54) ELECTRONIC CIRCUIT DEVICE AND METHOD FOR MANUFACTURING THE SAME

(71) Applicant: Murata Manufacturing Co., Ltd., Nagaokakyo-shi (JP)

(72) Inventor: Toshiyuki NAKAISO, Nagaokakyo-shi (JP)

(21) Appl. No.: 19/411,892

(22) Filed: Dec. 8, 2025

Related U.S. Application Data
(63) Continuation of application No. PCT/JP2024/018969, filed on May 23, 2024.

(30) Foreign Application Priority Data
Jun. 13, 2023 (JP) 2023-096990

(51) Int. Cl. H05K 1/18; H05K 3/28

(52) U.S. Cl. CPC H05K 1/181; H05K 3/284; H05K 2201/1003

(57) ABSTRACT

An electronic circuit device is provided that includes a chip component, a circuit board, and a coating resin. The chip component is mounted on the circuit board, and a mounting surface of the circuit board is coated with the coating resin. A surface of an element substrate, a surface of an insulator layer, and a surface of the coating resin form a continuous surface. The electronic circuit device includes an insulator exposed portion where there is no element substrate due to exposure of the insulator layer when viewed in a stacking direction of the element substrate and the insulator layer. At least a part of a coil opening by a coil conductor is in a region of the insulator exposed portion.

### CROSS REFERENCE TO RELATED APPLICATIONS

This application is a continuation of International Application No. PCT/JP2024/018969, filed May 23, 2024, which claims priority to Japanese Patent Application No. Application No. 2023-096990, filed June 13, 2023, the contents of each of which are hereby incorporated by reference in their entireties.

### TECHNICAL FIELD

The present disclosure relates to an electronic circuit device including a circuit board on which a chip component is mounted, and a method for manufacturing the same.

### BACKGROUND

In general, an integrated passive device (IPD) element configured by integrating a plurality of passive components on a single substrate is widely known. For the single substrate of an IPD element, a general Si substrate can be used as a substrate of a semiconductor element. Alternatively, in a case where an inductor is formed on the Si substrate, a glass substrate or a GaAs substrate can be used because there is a concern about loss due to an eddy current flowing through the Si substrate.

On the other hand, when an insulator substrate such as a GaAs substrate or a glass substrate is used, circuit components, such as a diode and a MOS capacitor, cannot be configured.

Japanese Patent Unexamined Publication Nos. 2001-77315 and 2007-49115 disclose that the loss due to the eddy current is suppressed by replacing a portion overlapping with the inductor in plan view with an insulating material without using the glass substrate or the GaAs substrate.

In the integrated circuit devices described in these Japanese Patent Unexamined Publications, in order to suppress a loss due to an eddy current generated in the Si substrate, a part of the Si substrate in a portion overlapping the inductor in plan view is replaced with an insulating material member.

However, when a part of the Si substrate is replaced with another insulating material member, the element itself becomes thin, or a portion of the Si substrate replaced with the insulating material member increases, so that the mechanical strength decreases. As a result, the integrated circuit device may be damaged by stress at the time of mounting the integrated circuit device on the circuit board or thermal shock and stress during mounting by reflow or the like.

### SUMMARY

Therefore, it is an object of the present disclosure to provide an electronic circuit device and a method for manufacturing the same, in which generation of an eddy current due to provision of an inductor in a chip component, stress during mounting of the chip component on a circuit board, and damage during mounting are suppressed.

In an exemplary aspect, an electronic circuit device of the present disclosure is provided that includes a chip component, a circuit board, and a coating resin. In this aspect, the chip component includes an element substrate having a first main surface and a second main surface that are opposite to each other; an insulator layer on a side of the first main surface of the element substrate; a coil conductor disposed inside the insulator layer and configured to generate or receive a magnetic flux having a vertical component of the first main surface of the element substrate; and a chip component side mounting electrode on the first main surface side and connecting the coil conductor or a circuit including the coil conductor to the circuit board. Moreover, the circuit board has a circuit board side electrode to which the chip component side mounting electrode is connected, the chip component side mounting electrode is connected to the circuit board side electrode, and the coating resin covers a mounting surface of the circuit board on which the chip component is mounted. The electronic circuit device also includes an insulator exposed portion in which the insulator layer surrounded by the element substrate is exposed, and a surface that includes the second main surface, the insulator exposed portion, and the coating resin of the element substrate forms a continuous surface. At least a part of a coil opening formed by the coil conductor is in a formation region of the insulator exposed portion when viewed in a direction perpendicular to the second main surface of the element substrate.

In another exemplary aspect, a method is provided for manufacturing an electronic circuit device. In this aspect, the exemplary method includes forming a chip component by forming a recess on a side of a first main surface of an element substrate having the first main surface and a second main surface that are opposite to each other, forming an insulator inside the recess, forming an insulator layer on the side of the first main surface of the element substrate, forming a coil conductor that is configured to generate or receive a magnetic flux having a vertical component with respect to the insulator layer on the insulator layer, and forming a chip component side mounting electrode that connects the coil conductor or a circuit including the coil conductor on a circuit board. In addition, the method includes forming a circuit board side electrode to which the chip component side mounting electrode is connected on the circuit board; connecting the chip component side mounting electrode to the circuit board side electrode; coating a mounting surface of the chip component on the circuit board with a coating resin; and grinding the element substrate and the insulator layer from the second main surface side until the insulator inside the recess is exposed from the element substrate to form a continuous surface on a surface including the second main surface of the element substrate, the insulator inside the recess, and the coating resin.

According to the exemplary aspects of the present disclosure, an electronic circuit device and a method for manufacturing the same is provided in which generation of an eddy current due to provision of the inductor in the chip component, stress during mounting of the chip component on the circuit board, and damage during mounting are suppressed.

### BRIEF DESCRIPTION OF DRAWINGS

FIG. 1 is a cross-sectional view of an electronic circuit device 301 according to a first exemplary embodiment.

FIGS. 2 and 3 are cross-sectional views illustrating a method for manufacturing the electronic circuit device 301 according to the first exemplary embodiment.

FIG. 4 is a diagram illustrating a coil conductor 6 that generates or receives a magnetic flux φ having a vertical component with respect to insulator layers 4, 5A, and 5B.

FIG. 5 is a diagram illustrating a positional relationship and a shape of a surface of an element substrate 1, a surface of an insulator exposed portion 4S, and a surface of a coating resin 10.

FIG. 6(a) is a plan view of an electronic circuit device 302 according to a second exemplary embodiment, and FIG. 6(b) is a longitudinal cross-sectional view taken along a one-dot chain line in the plan view according to the second exemplary embodiment.

FIG. 7 is a cross-sectional view of a chip component 102 before being mounted on a circuit board 201.

FIG. 8 is a cross-sectional view illustrating a method for manufacturing the electronic circuit device 302 according to the second exemplary embodiment.

FIGS. 9(a) to 9(d) are plan views illustrating shape of in-groove insulators 32 different from the example illustrated in FIGS. 6(a) and 6(b).

FIG. 10 is a cross-sectional view of an electronic circuit device 303 according to a third exemplary embodiment.

FIG. 11 is a diagram illustrating a method for manufacturing an electronic circuit device 304 according to a fourth exemplary embodiment.

FIGS. 12-16 are cross-sectional views illustrating a method for manufacturing an electronic circuit device according to a fifth embodiment.

FIG. 16 is a plan view in a state indicated by step (10) in FIG. 15.

FIG. 17 is a circuit diagram of a circuit by an electronic circuit device 305 configured at a predetermined position on the circuit board.

### DETAILED DESCRIPTION OF EMBODIMENTS

Hereinafter, a plurality of modes for carrying out the exemplary aspects of the present disclosure will be shown with some specific examples with reference to the drawings. In each figure, the same parts are designated by the same reference signs. In consideration of the description of the main points or ease of understanding, it is noted that the embodiment is divided into a plurality of embodiments for convenience of description, but partial replacement or combination of configurations shown in different embodiments is possible. In second and subsequent embodiments, description of matters common to a first embodiment will be omitted, and only different points will be described. In particular, similar actions and effects obtained by the same configuration will not be sequentially described for each embodiment.

### First Exemplary Embodiment

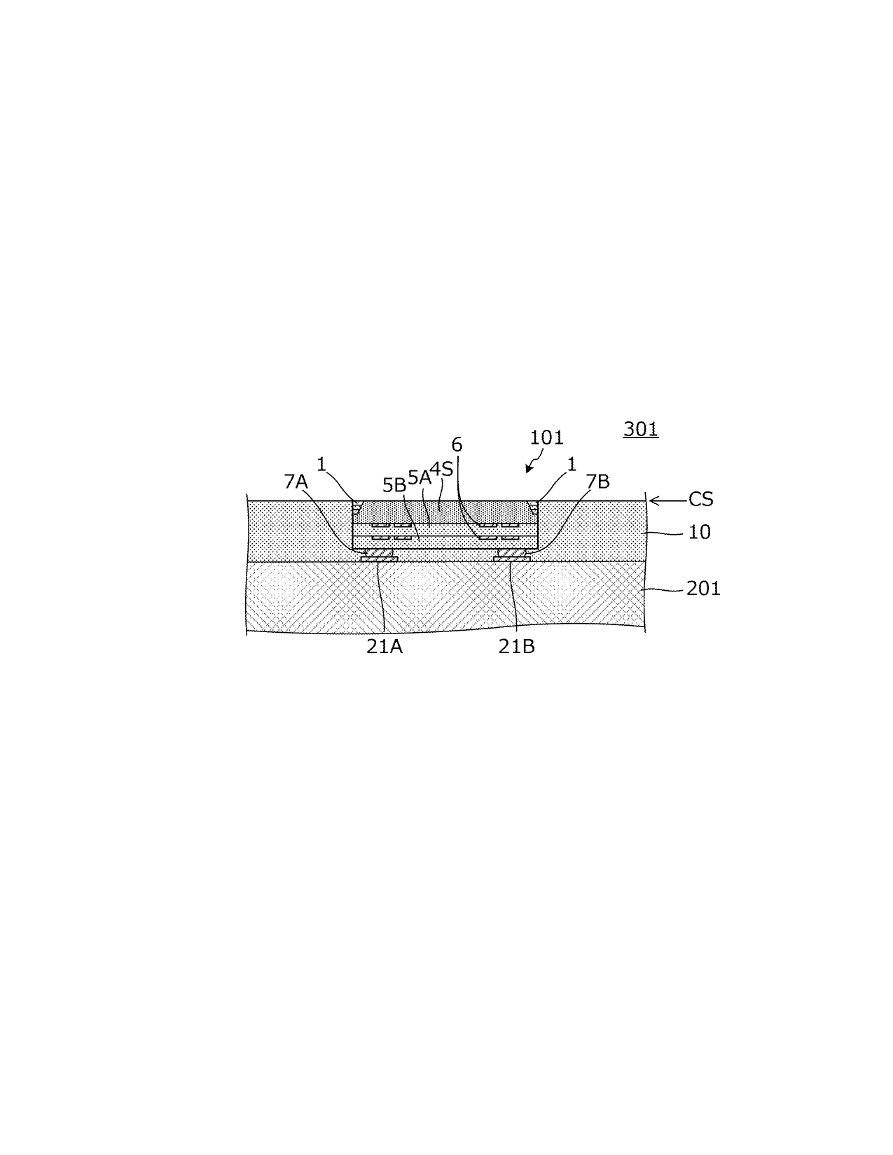

FIG. 1 is a cross-sectional view of an electronic circuit device 301 according to a first exemplary embodiment. As shown, the electronic circuit device 301 includes a chip component 101, a circuit board 201, and a coating resin 10.

The chip component 101 includes an element substrate (this will be described in detail later) 1, an insulator exposed portion 4S, and insulator layers 5A and 5B. According to an exemplary aspect, the insulator exposed portion 4S can be defined as an insulator embedded in the element substrate 1. The insulator exposed portion 4S will be described in detail later. The element substrate 1 has a first main surface and a second main surface that are opposite to each other. The insulator exposed portion 4S is exposed on a surface continuing to the second main surface (i.e., the upper surface in FIG. 1) of the element substrate 1. In the insulator layers 5A and 5B, the coil conductor 6 that generates the magnetic flux of the vertical direction (up-down direction or thickness direction in FIG. 1) component of the first main surface of the element substrate 1 or receives the magnetic flux component in the direction is formed. The coil conductor 6 is formed in the stacking direction of the insulator exposed portion 4S and the insulator layers 5A and 5B to form a spiral, helical, or spiral helical mixed coil.

Further, chip component side mounting electrodes 7A and 7B that connect a circuit to the circuit board 201 are formed on the chip component 101.

On the circuit board 201, circuit board side electrodes 21A and 21B to which the chip component side mounting electrodes 7A and 7B of the chip component 101 are connected are formed.

The chip component side mounting electrodes 7A and 7B are connected to the circuit board side electrodes 21A and 21B of the circuit board 201, respectively.

The mounting surface of the circuit board 201 on which the chip component 101 is mounted is coated with the coating resin 10 so as to surround the chip component 101.

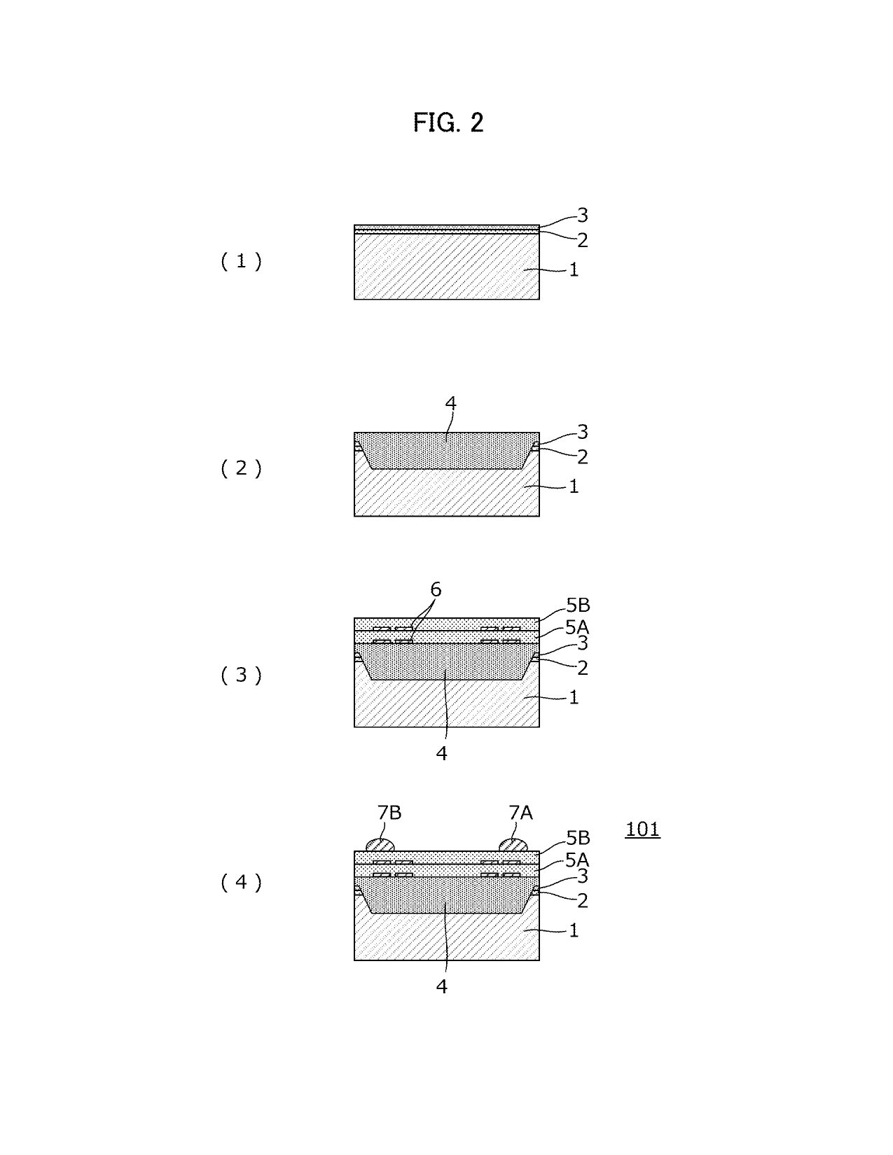

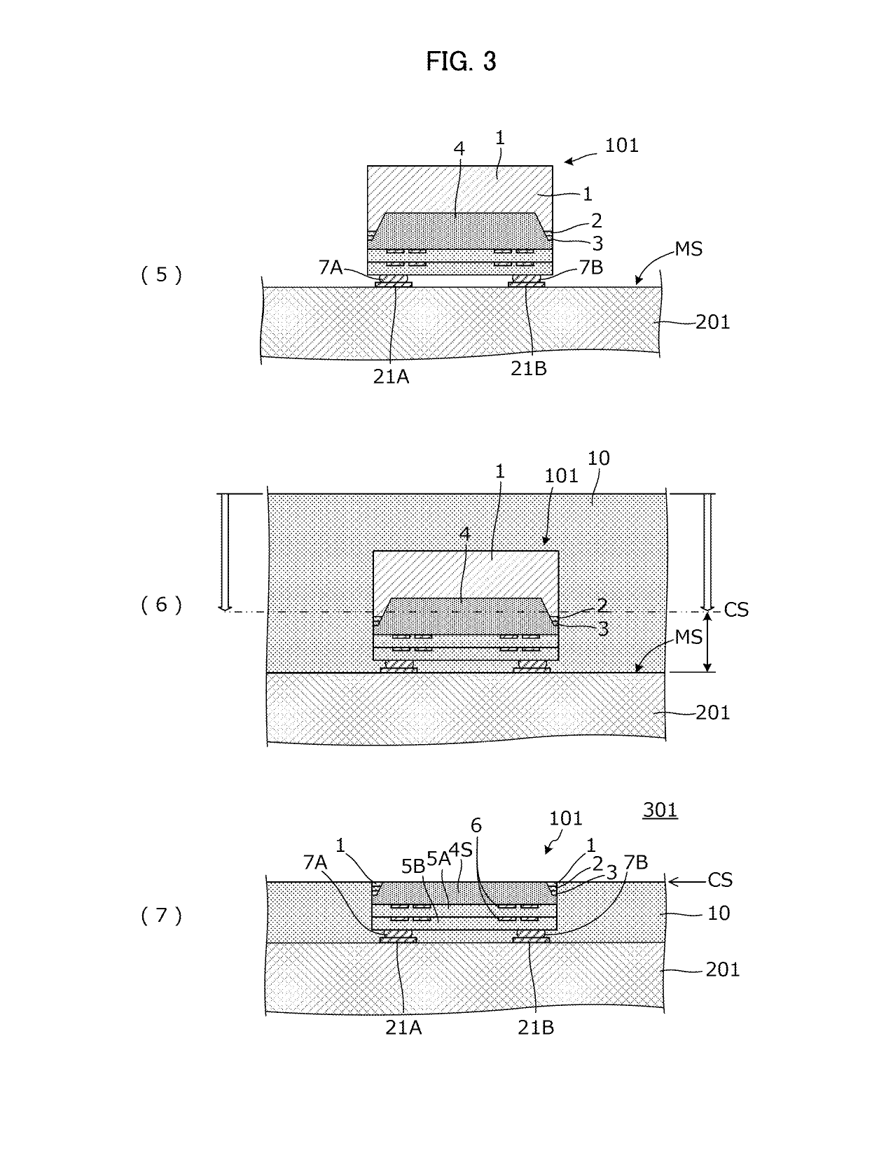

FIGS. 2 and 3 are cross-sectional views illustrating the method for manufacturing the electronic circuit device 301 according to the first embodiment. According to the exemplary aspect, steps (1) to (7) illustrated in FIGS. 2 and 3 are numbers indicating a procedure of a schematic process. However, it is noted that although steps (1) to (4) are illustrated in the state of a single chip component for convenience of description, the manufacture is actually performed in a wafer state in which a plurality of chip components are arranged. In addition, steps (5) to (7) illustrate a portion of the electronic circuit device in a state after being separated into a single chip component. Hereinafter, the contents will be described in order of process numbers.

As shown in step (1), for example, an oxide film 2 such as SiO2 is formed on a surface of the element substrate 1 such as a Si substrate, and a passivation film such as a nitride film (Si2N4) is formed on the surface by CVD or the like.

As shown in step (2), a recess having a predetermined depth is formed from the surface of the passivation film to the element substrate 1, and the insulator layer 4 is formed from the bottom surface of the recess to a position at a predetermined height from the passivation film by, for example, dry etching or sandblasting. The insulator layer 4 can be an organic insulating film for leveling that flattens the surface thereof, and is, for example, an organic film such as an epoxy resin, polyimide polybenzoxazole (PBO), or polyimide (PI).

As shown in step (3), the insulator layers 5A and 5B are formed on the surface of the insulator layer 4, and the coil conductor 6 is formed of a conductor member such as Cu or Al. For example, Ti and TiN of 10 nm to 100 nm are formed on the upper and lower surfaces of the coil conductor 6. By forming the Ti and TiN films, the adhesion to the resin layer is improved.

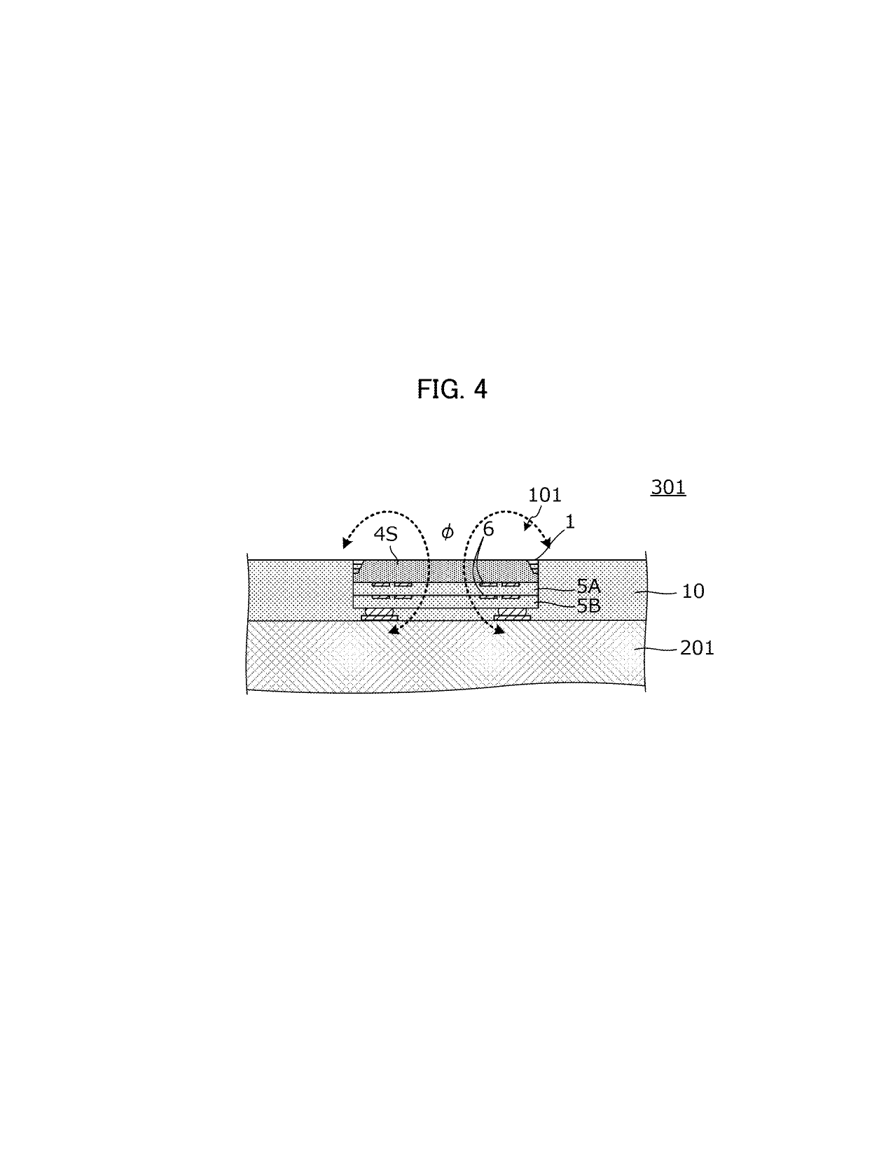

As shown in step (4), on the surface of the insulator layer 5B on the surface, the chip component side mounting electrodes 7A and 7B are formed by soldering or the like. The main part of the chip component 101 is configured by the processes up to step (4). It is noted that in step (4) of FIG. 2 and subsequently in FIG. 4, the patterns of the connecting portions between the chip component side mounting electrodes 7A and 7B and the coil conductor 6 are not illustrated. Specific examples of the planar shape and interlayer connection of the coil conductor 6 and the connection structure with the chip component side mounting electrodes 7A and 7B will be described later.

As shown in step (5) in FIG. 3, the chip component side mounting electrodes 7A and 7B of the chip component 101 are connected to the circuit board side electrodes 21A and 21B formed on the circuit board 201, respectively. That is, the chip component 101 is mounted on a mounting surface MS of the circuit board 201. For example, the chip component 101 is mounted at a position where the chip component side mounting electrodes 7A and 7B face the circuit board side electrodes 21A and 21B and is soldered by heating. Note that the chip component side mounting electrode of the chip component 101 may be a simple electrode, and soldering may be performed by applying solder paste to the circuit board side electrodes 21A and 21B formed on the circuit board 201, mounting the chip component side mounting electrodes 7A and 7B, and heating the chip component side mounting electrodes 7A and 7B.

As shown in step (6), the mounting surface MS of the chip component 101 on the circuit board 201 is coated with the coating resin 10. The coating height of the coating resin 10 is higher than the upper surface of the chip component 101.

According to step (7), as illustrated in step (6) in FIG. 3, the coating resin 10, the element substrate 1, and the insulator layer 4 are ground to a depth to become the chip surface CS later. As a result, the element substrate 1 and the insulator layer 4 of the chip component 101 are partially removed. As described above, the insulator exposed portion 4S can be defined as an exposed portion of the insulator layer 4 embedded in the element substrate 1.

Through this grinding process, as will be described later in detail, a continuous surface (e.g., a ground surface) having no angular step portion is formed on the surfaces of the insulator layer 4, the element substrate 1, and the coating resin 10. It is noted that the term “continuous surface” refers to a “flat surface”, a “substantially flat surface”, a “flat continuous surface”, or the like. In addition, when there are protrusions of various angles such as an acute angle protrusion and an obtuse angle protrusion, the term “continuous surface” refers to a surface in which the ratio of the acute angle protrusion is smaller than the ratio of the obtuse angle protrusion. The step portion will be described in detail later. By this grinding, the insulator layer 4 is exposed to form the insulator exposed portion 4S. As a result, at least a part of the coil opening of the coil conductor 6 is disposed in the insulator exposed portion 4S.

As described above, by grinding the coating resin 10, the element substrate 1, and the insulator layer 4 to the depth to become the chip surface CS, the insulator exposed portion 4S can be formed by exposing the insulator layer 4, but the fact that the insulator exposed portion 4S having no element substrate has a tapered shape in the direction from the coil conductor 6 to the element substrate 1 may be used. That is, as illustrated in step (3) in FIG. 2 to step (7) in FIG. 3 and the like, since the area of the insulator exposed portion 4S on the second main surface of the element substrate 1 is smaller than the area of the insulator exposed portion 4S on the first main surface of the element substrate 1, that is, the insulator exposed portion 4S has a tapered shape, the exposed area of the insulator layer 4 changes according to the grinding amount of the chip component 101 as illustrated in step (6) and step (7) in FIG. 3. Therefore, the grinding amounts of the coating resin 10 and the chip component 101 can be easily determined so that the exposed area is appropriate.

FIG. 4 is a diagram illustrating the coil conductor 6 that generates or receives the magnetic flux φ component in the direction perpendicular to the insulator exposed portion 4S and the insulator layers 5A and 5B. Since the area of the element substrate 1 of the chip component 101 is small and the element substrate 1 is outside the coil opening, the magnetic flux φ is hardly blocked by the element substrate 1 of the chip component 101. In the exemplary aspect, the coating resin 10 is not a magnetic body. The circuit board 201 is also not a magnetic body or hardly includes a magnetic body portion. Therefore, the loss due to the eddy current is suppressed.

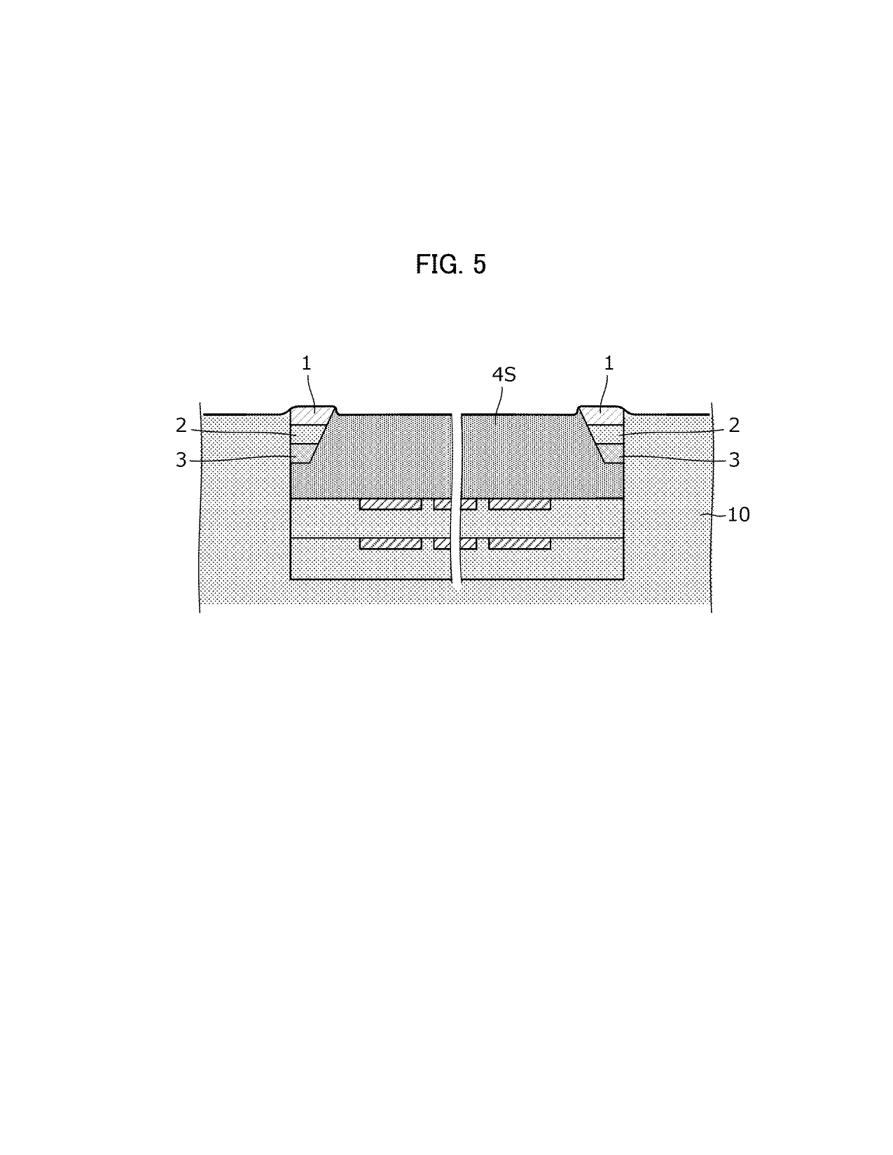

FIG. 5 is a diagram illustrating a positional relationship and a shape of a surface of an element substrate 1, a surface of an insulator exposed portion 4S, and a surface of a coating resin 10. As illustrated in FIG. 5, since the element substrate 1 is a Si substrate or the like and is harder than the insulator resin, when the coating resin 10, the element substrate 1, and the insulator layer 4 are simultaneously ground to the depth to become the chip surface CS as illustrated in step (6) and step (7) in FIG. 3, the element substrate 1 protrudes from the coating resin 10 and the insulator exposed portion 4S. However, since the element substrate 1, the insulator exposed portion 4S, and the coating resin 10 are integrated, the surface of the element substrate 1, the surface of the insulator exposed portion 4S, and the surface of the coating resin 10 form a continuous surface without angular step portions such as peaks and recesses. As described above, the term “continuous surface” can refer to, for example, a “flat surface”, a “substantially flat surface”, a “flat continuous surface”, or the like. That is, even if the element substrate 1 protrudes, it corresponds to “the surface of the element substrate 1, the surface of the insulator exposed portion 4S, and the surface of the coating resin 10 form a continuous surface”. In addition, since the grinding is performed on a surface, only the element substrate 1 is ground in a case where the element substrate 1 largely protrudes, and thus, a substantially flat continuous surface is obtained when viewed as the entire electronic circuit device.

According to the present embodiment, by mounting the element substrate 1 on the circuit board in a state where the element substrate 1 has a sufficient thickness, fixing the chip component and the circuit board with the coating resin, and then removing the unnecessary Si substrate portion, it is possible to achieve both the mounting of the chip component, the securing of the mechanical strength at the time of coating with the coating resin, and the improvement of the electrical characteristics by suppressing the eddy current, and it is also possible to realize the thinning of the entire circuit device.

### Second Exemplary Embodiment

In a second exemplary embodiment, a chip component and an electronic circuit device in which an insulator forming portion is formed inside an element substrate and an insulator exposing portion in which the insulator forming portion is exposed from the inside of the element substrate will be exemplified.

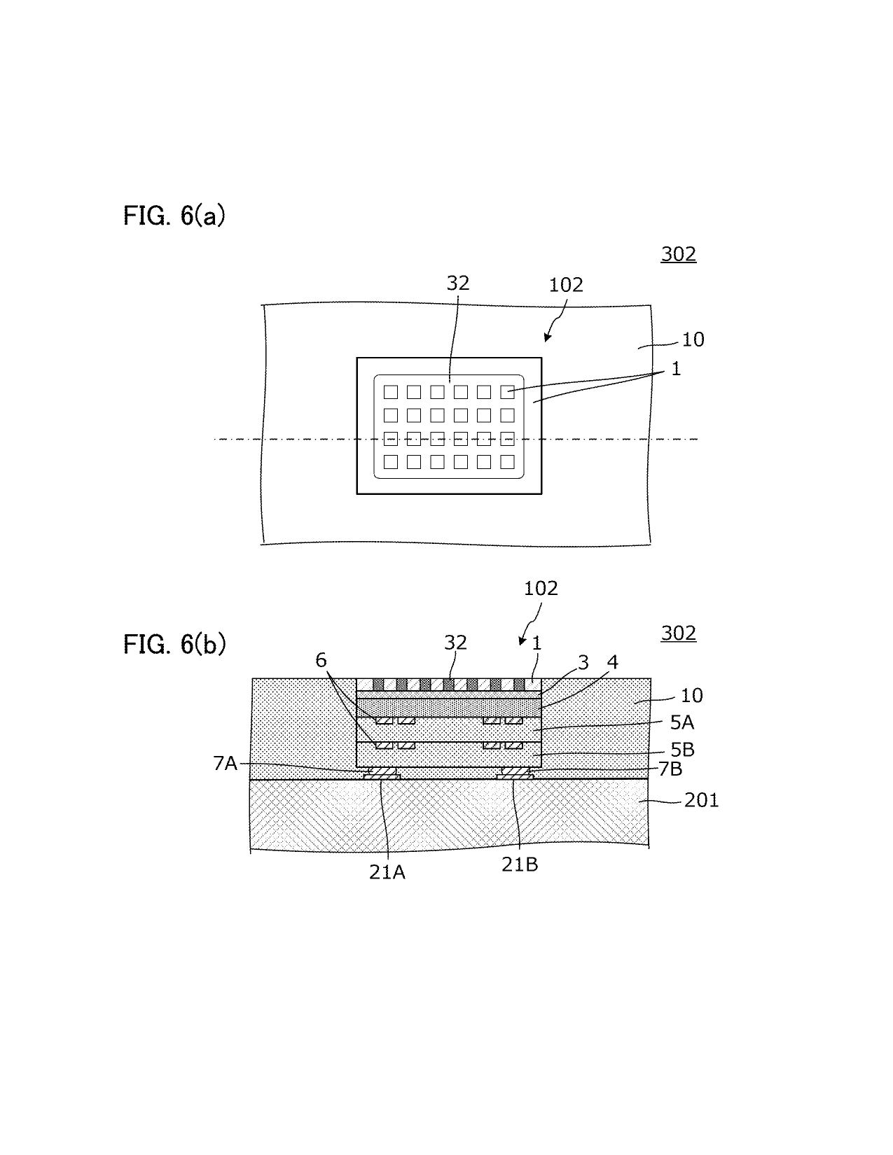

In particular, FIG. 6(a) is a plan view of an electronic circuit device 302 according to a second exemplary embodiment, and FIG. 6(b) is a longitudinal cross-sectional view taken along a one-dot chain line in the plan view shown in FIG. 6(a).

The electronic circuit device 302 includes a chip component 102, a circuit board 201, and a coating resin 10.

The chip component 102 includes an element substrate 1, a passivation film 3, insulator layers 4, 5A, and 5B, a coil conductor 6, chip component side mounting electrodes 7A and 7B, and the like.

An in-groove insulator 32 is exposed on the surface of the element substrate 1. The coil conductor 6 is formed in the insulator layer 4 and the insulator layer 5A, and is configured to generate a magnetic flux component in a direction perpendicular to the insulator layer 4 (up-down direction or thickness direction in FIG. 1) or receives a magnetic flux component in the direction. The coil conductor 6 is formed in the stacking direction of the insulator layers 4, 5A, and 5B to form a spiral or helical coil circuit.

On the circuit board 201, circuit board side electrodes 21A and 21B to which the chip component side mounting electrodes 7A and 7B of the chip component 102 are connected are formed.

The chip component side mounting electrodes 7A and 7B are connected to the circuit board side electrodes 21A and 21B of the circuit board 201.

The mounting surface of the circuit board 201 on which the chip component 102 is mounted is coated with the coating resin 10.

In this manner, the in-groove insulator 32 is distributed in the element substrate 1, and the in-groove insulator 32 is spread in the element substrate 1. Therefore, the area of the element substrate 1 of the chip component 102 is small. In addition, a current loop of the eddy current that is about to flow into the element substrate 1 becomes small. Therefore, the loss due to the eddy current can be suppressed.

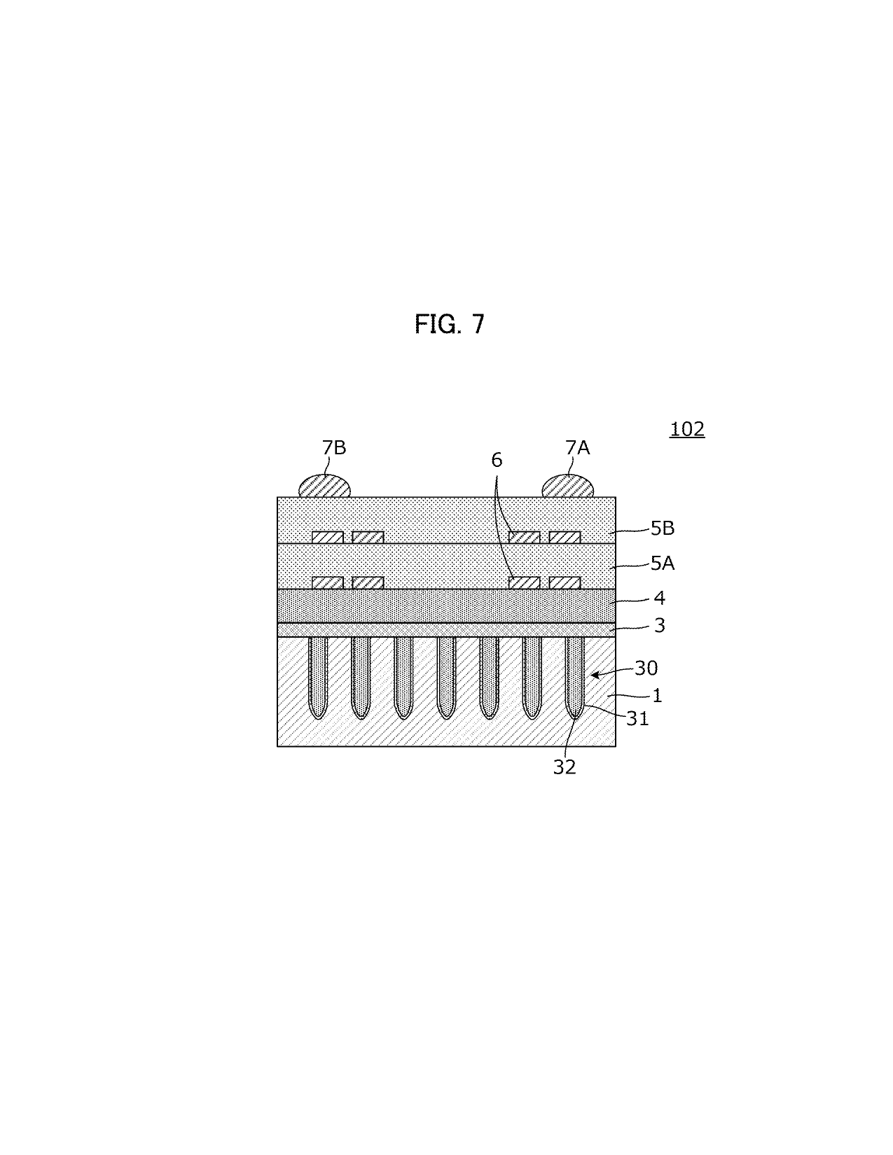

FIG. 7 is a cross-sectional view of the chip component 102 before being mounted on the circuit board 201 illustrated in FIG. 6. The groove (trench) 30 is formed from the surface of the element substrate 1 inside the element substrate 1 such as a Si substrate, the in-groove insulator 31 made of an inorganic oxide film such as SiO2 is formed on the inner surface of the groove, and the in-groove insulator 32, such as polysilicon, is formed inside the groove.

The passivation film 3 is formed on the upper surface of the element substrate 1, and the insulator layers 4, 5A, and 5B are formed on an upper portion of the passivation film 3. The coil conductor 6 is formed on the upper surface of the insulator layer 4 and the upper surface of the insulator layer 5A. The chip component side mounting electrodes 7A and 7B are formed on the upper surface of the insulator layer 5B.

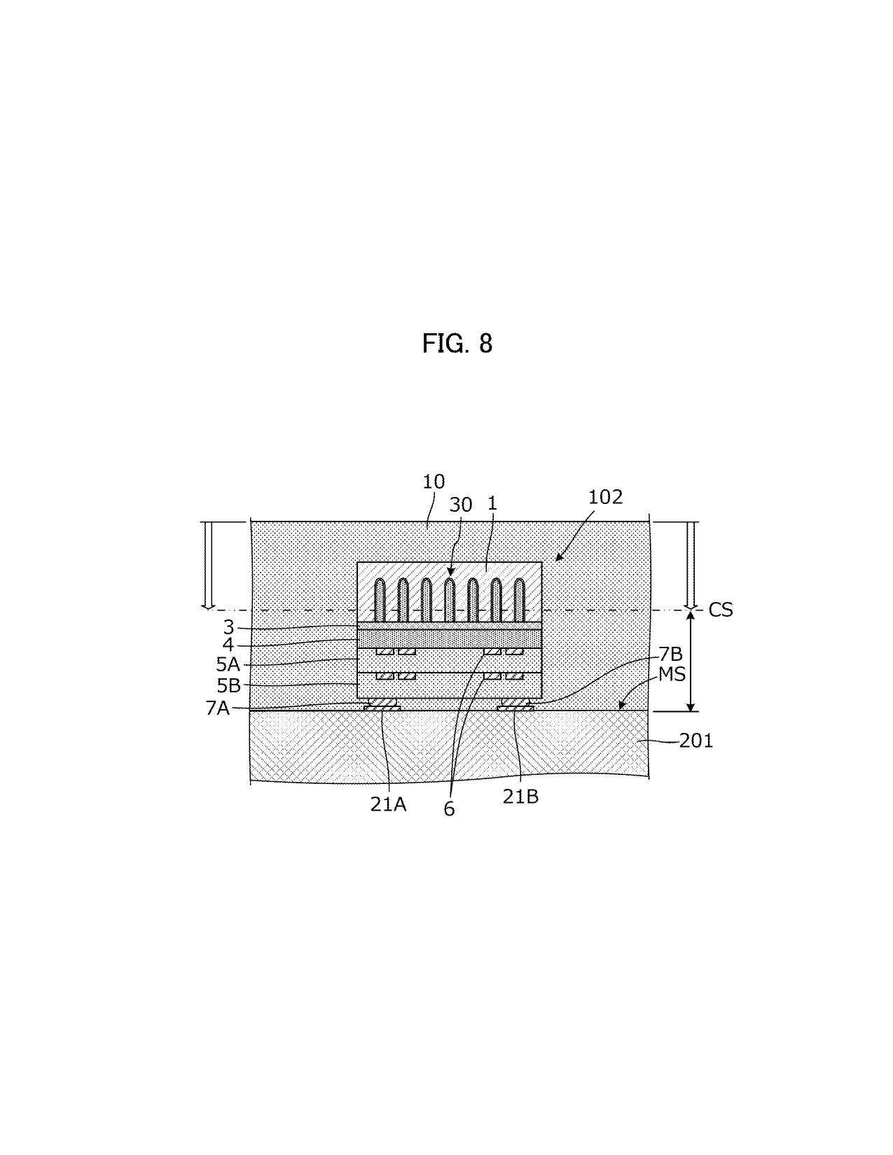

FIG. 8 is a cross-sectional view illustrating a method for manufacturing the electronic circuit device 302 according to the second exemplary embodiment. First, the chip component side mounting electrodes 7A and 7B of the chip component 102 are connected to the circuit board side electrodes 21A and 21B formed on the circuit board 201. That is, the chip component 102 is mounted on the mounting surface MS of the circuit board 201. For example, the chip component 102 is mounted at a position where the chip component side mounting electrodes 7A and 7B face the circuit board side electrodes 21A and 21B and is soldered by heating. It is noted that the chip component side mounting electrode of the chip component 102 may be a simple electrode according to an exemplary aspect, and soldering may be performed by applying solder paste to the circuit board side electrodes 21A and 21B formed on the circuit board 201, mounting the chip component side mounting electrodes 7A and 7B, and heating the chip component side mounting electrodes 7A and 7B.

Next, the mounting surface MS of the circuit board 201 for the chip component is coated with the coating resin 10. The coating height of the coating resin 10 is higher than the upper surface of the chip component 102.

As illustrated in FIG. 8, the coating resin 10, the element substrate 1, and the groove 30 are ground to a depth to become the chip surface CS later. As a result, the element substrate 1 and the in-groove insulators 31 and 32 of the chip component 102 are partially removed. As a result, a continuous surface (e.g., ground surface) having no angular step portion is formed on the surfaces of the in-groove insulators 31 and 32, the element substrate 1, and the coating resin 10. The in-groove insulators 31 and 32 are exposed by grinding the coating resin 10 to form exposed portions of the in-groove insulators 31 and 32. As a result, at least a part of the coil opening of the coil conductor 6 is within the formation region of the insulator exposed portion as viewed in the stacking direction of the element substrate 1 and the insulator layers 4, 5A, and 5B.

It is noted that in FIGS. 6(a), 6(b), 7 and 8, the pattern of the connection portion between the chip component side mounting electrodes 7A and 7B and the coil conductor 6 is not illustrated.

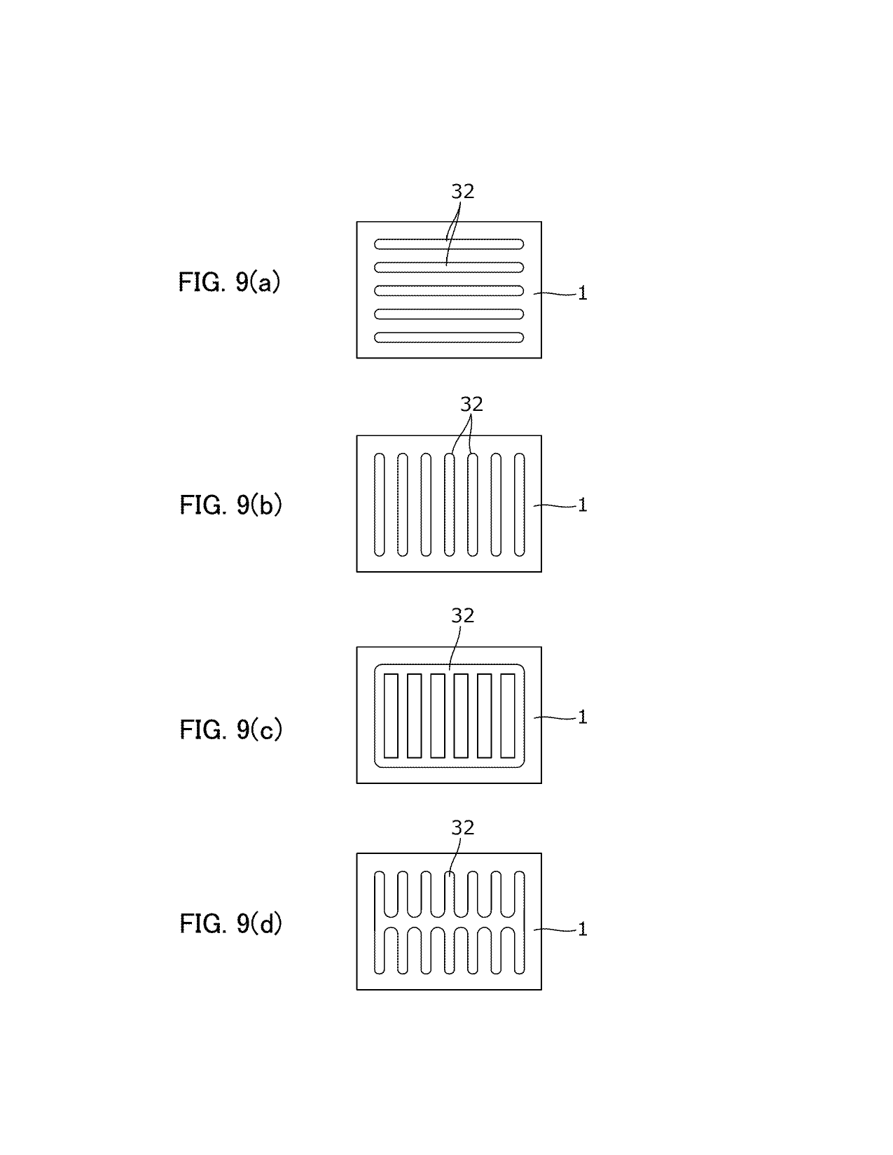

FIGS. 9(a) to 9(d) are plan views illustrating shapes of in-groove insulators 32 different from the example illustrated in FIGS. 6(a) and 6(b). In the chip component in FIG. 9(a), a plurality of in-groove insulators 32 extending horizontally are formed on the element substrate 1. In the chip component illustrated in FIG. 9(b), a plurality of in-groove insulators 32 extending vertically are formed on the element substrate 1. Even in such a pattern of the in-groove insulator 32, the area of the element substrate 1 is small, and the current loop of the eddy current that is about to flow into the element substrate 1 is small. In the chip component illustrated in FIG. 9(c), an in-groove insulator 32 having a vertical lattice shape is formed on the element substrate 1. As described above, by closing the eddy current path flowing in the element substrate 1 with the in-groove insulator 32, the current loop of the eddy current that is about to flow in the element substrate 1 becomes effectively small. In the chip component illustrated in FIG. 9(d), an in-groove insulator 32 having a plurality of portions extending in the longitudinal direction and a portion continuing the portions in the lateral direction is formed on the element substrate 1. Even with such a shape, the current loop of the eddy current that is about to flow into the element substrate 1 is effectively small.

According to the present embodiment, since the grinding speed of SiO2 is lower than that of Si, even if processing is performed at a high speed from the start of grinding to the trench, the grinding speed decreases when the trench is reached. Therefore, the grinding amount can be controlled with high accuracy after reaching the trench while shortening the time required for manufacturing by the high-speed processing.

### Third Exemplary Embodiment

In a third exemplary embodiment, an electronic circuit device in which a chip component is sealed will be exemplified.

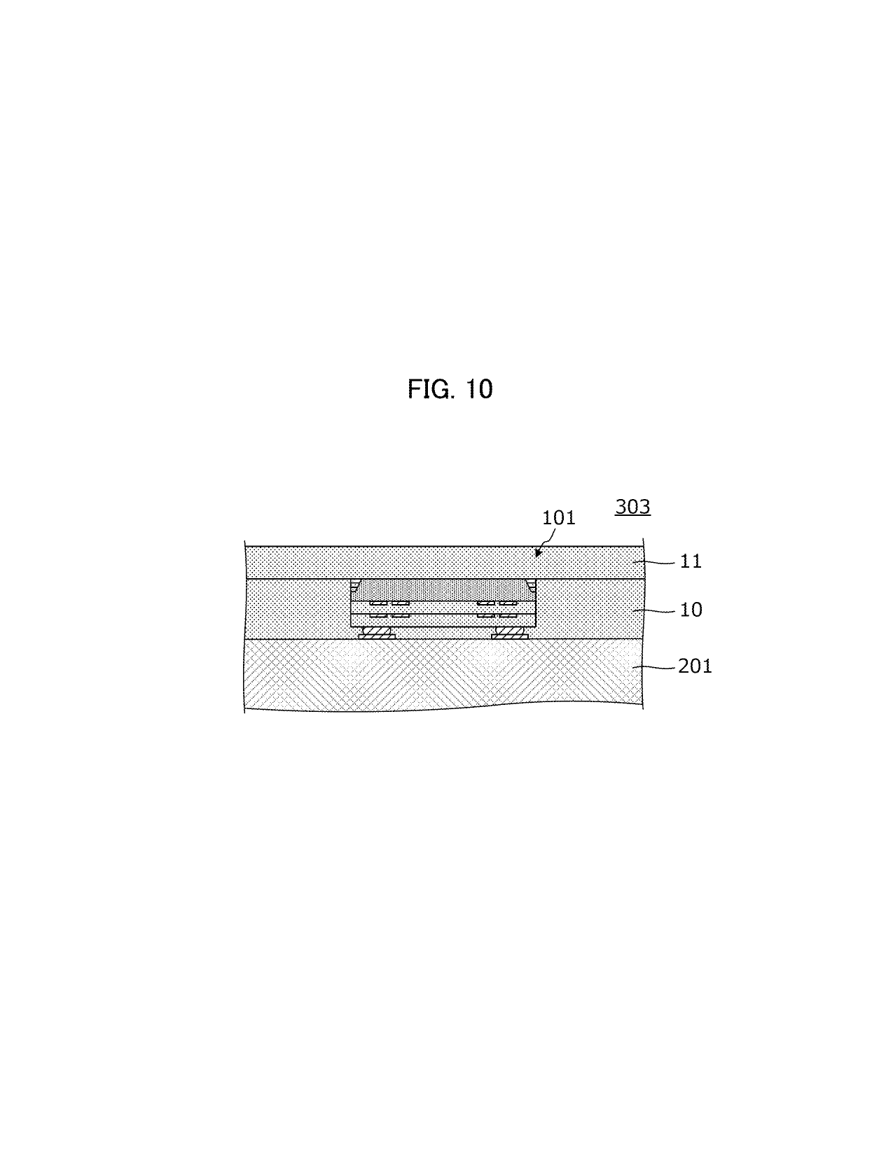

FIG. 10 is a cross-sectional view of an electronic circuit device 303 according to a third exemplary embodiment. In the electronic circuit device 303, a chip component 101 is mounted on a circuit board 201, a mounting surface of the circuit board 201 on which the chip component 101 is mounted is covered with a coating resin 10, and upper surfaces of the chip component 101 and the coating resin 10 are covered with a sheath protective resin 11.

The electronic circuit device 303 has a structure in which the upper surface of the electronic circuit device 301 illustrated in FIG. 1 is further covered with the sheath protective resin 11.

As shown in the present embodiment, the chip component 101 mounted on the circuit board 201 may be coated with the coating resin 10 and the sheath protective resin 11. As a result, the external environment of the chip component 101 is improved while thinning and flatness of the electronic circuit device 303 are maintained.

### Fourth Exemplary Embodiment

In a fourth embodiment, a shape of a coating resin different from those of the embodiments described above and a method for forming the same will be exemplified.

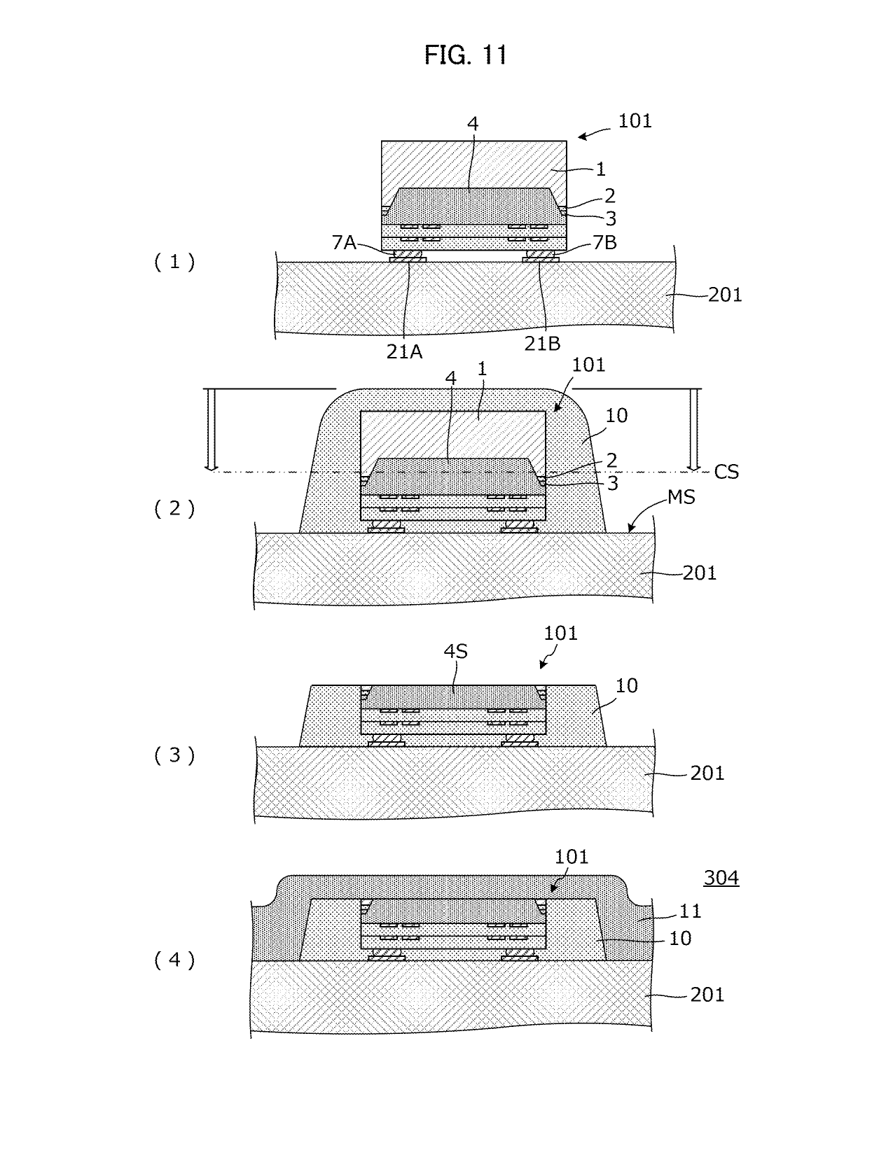

Steps (1) to (4) illustrated in FIG. 11 are numbers indicating a procedure of a schematic process. Hereinafter, the contents will be described in order of process numbers.

In step (1), the chip component side mounting electrodes 7A and 7B of the chip component 101 are connected to the circuit board side electrodes 21A and 21B formed on the circuit board 201. That is, the chip component 101 is mounted on a mounting surface MS of the circuit board 201.

In step (2), the mounting surface MS of the chip component 101 on the circuit board 201 is coated with the coating resin 10. The coating planar range of the coating resin 10 is a size that covers the chip component 101. The height of the coating resin 10 is higher than the upper surface of the chip component 101.

In step (3), as illustrated in step (2) in FIG. 11, the coating resin 10, the element substrate 1, and the insulator layer 4 are ground to a depth to become the chip surface CS later. As a result, the element substrate 1 and the insulator layer 4 of the chip component 101 are partially removed.

In step (4), the mounting surface of the circuit board 201 on which the chip component 101 is mounted is covered with the sheath protective resin 11.

### Fifth Exemplary Embodiment

In a fifth embodiment, an electronic circuit device in which a circuit element other than a coil conductor is formed at a position where an element substrate exists as viewed in a stacking direction of the element substrate and an insulator layer will be exemplified.

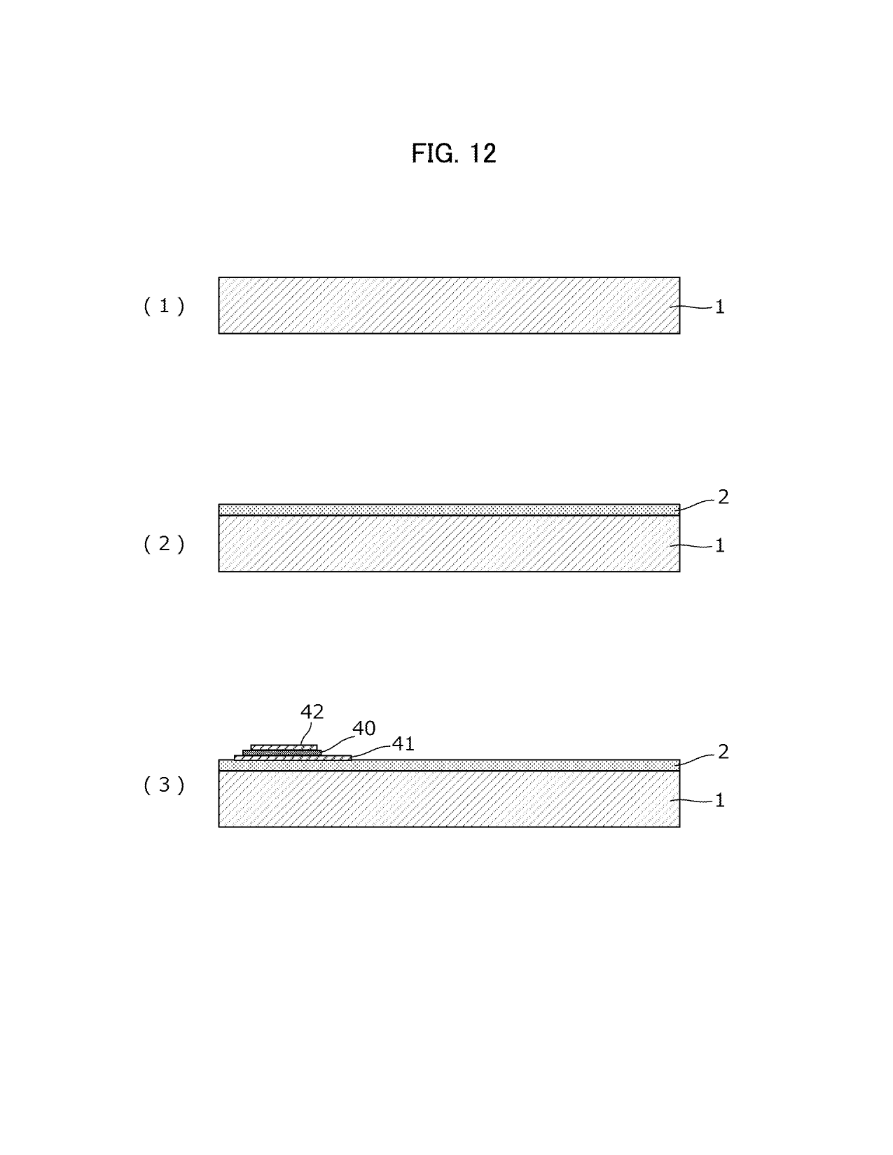

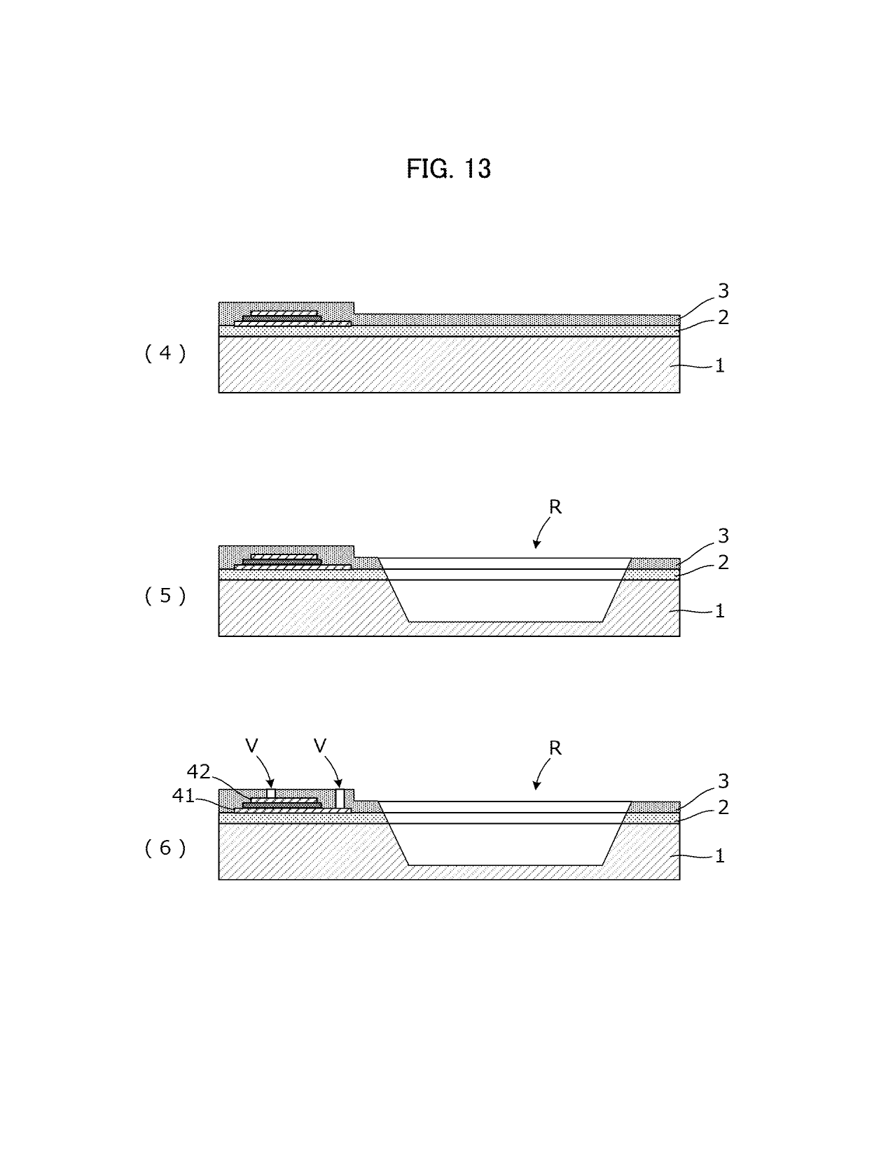

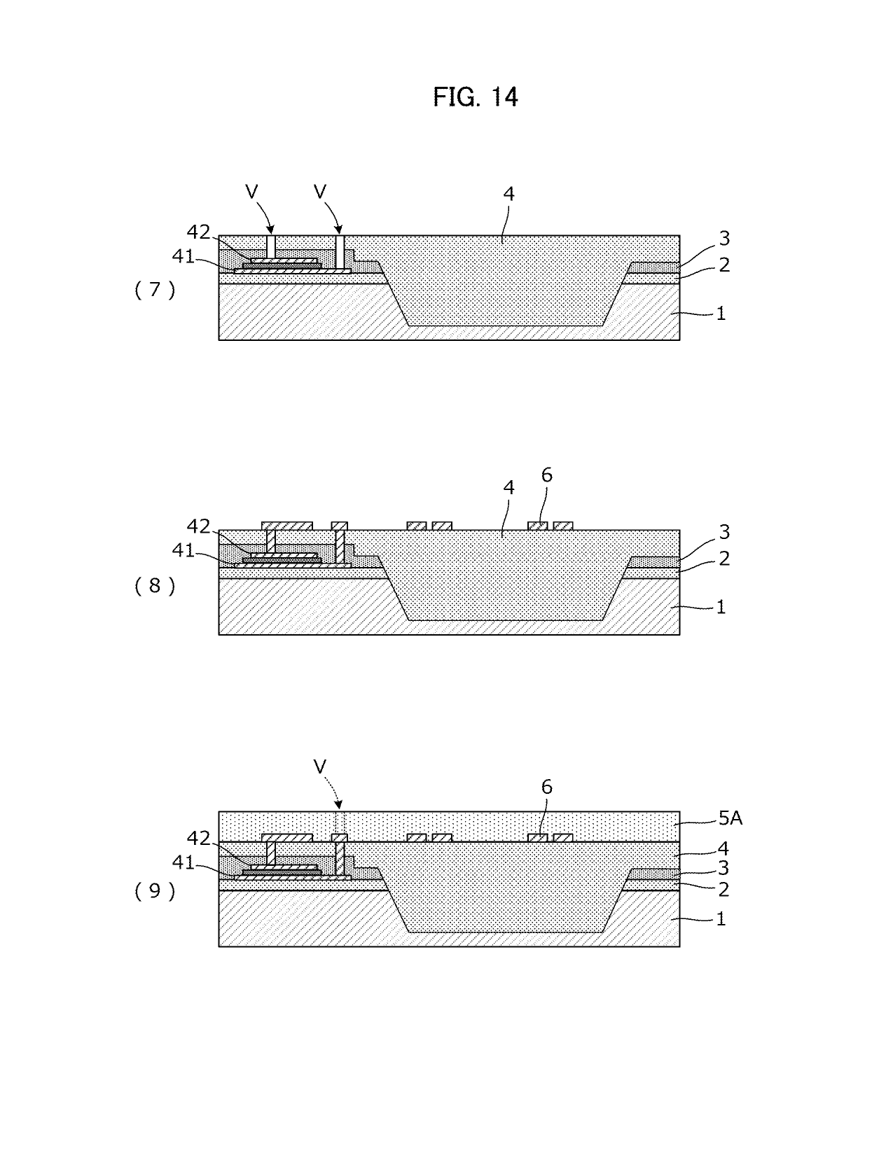

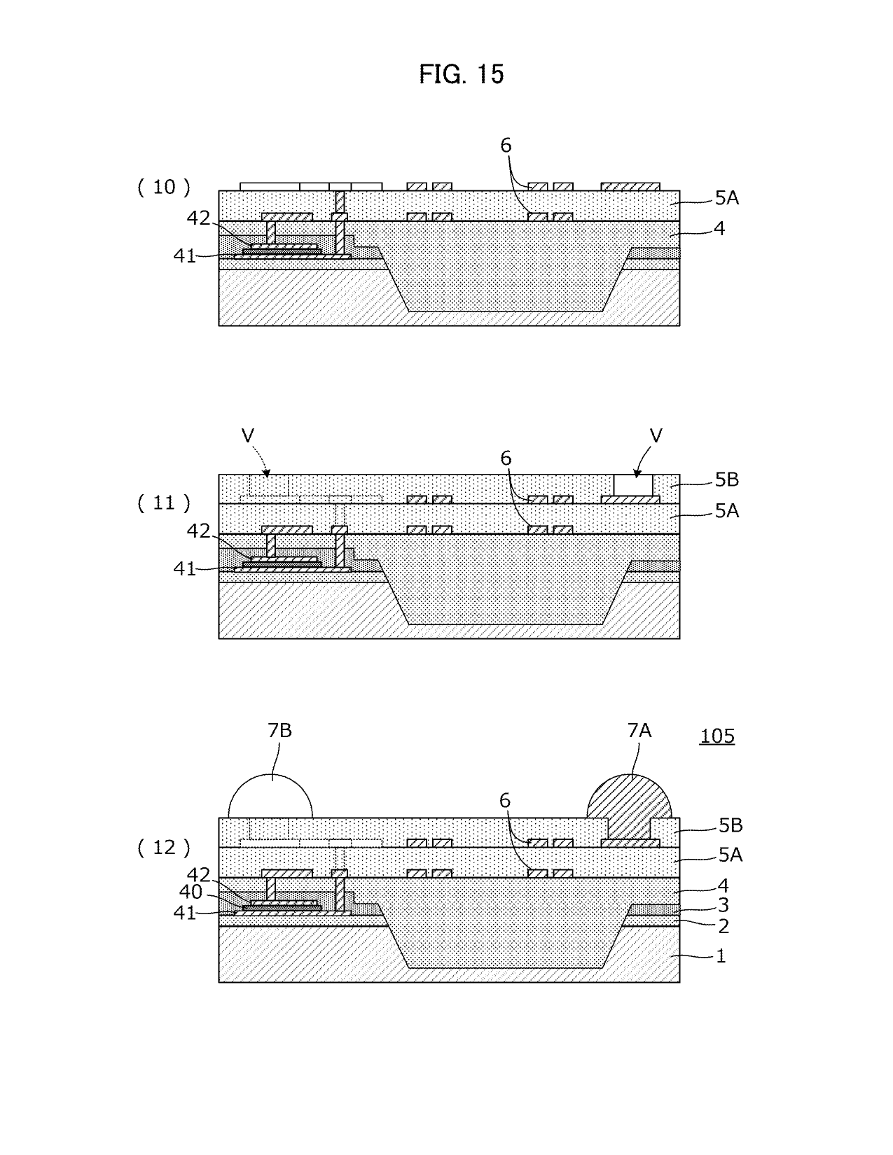

FIGS. 12 to 15 are cross-sectional views illustrating a method for manufacturing an electronic circuit device according to a fifth exemplary embodiment. In particular, steps (1) to (12) illustrated in FIGS. 12 to 15 are numbers indicating a procedure of a schematic process. Hereinafter, the contents will be described in order of process numbers.

As shown in step (1), for example, the element substrate 1 such as a Si substrate is put into a manufacturing apparatus.

As shown in step (2), the oxide film 2 such as SiO2 is formed on the surface of the element substrate 1.

As shown in step (3), a capacitor electrode 41 is formed on the surface of the oxide film 2, and is formed in a predetermined pattern. A dielectric layer 40 is formed on the upper surface of the capacitor electrode 41 and is formed in a predetermined pattern. A capacitor electrode 42 is formed on the upper surface of the dielectric layer 40 and is formed in a predetermined pattern. The dielectric layer 40 and the capacitor electrodes 41 and 42 form a capacitor.

As shown in step (4), the passivation film 3 is formed over the entire region including the capacitor by CVD or the like.

As shown in step (5), a recess R having a predetermined depth from the surface of the passivation film 3 to the element substrate 1 is formed by, for example, dry etching or sandblasting.

As shown in step (6), holes (vias) V reaching the capacitor electrodes 41 and 42 are formed by trial etching or the like, for example. Note that the recess illustrated in (5) may be formed after these holes V are formed.

As shown in step (7), the insulator layer 4 is formed from the bottom surface of the recess R to a position at a predetermined height from the passivation film 3. The insulator layer 4 is an organic insulating film for leveling that flattens the surface thereof, and is, for example, a photosensitive organic film such as an epoxy resin, polyimide polybenzoxazole (PBO), or polyimide (PI).

As shown in step (8), a first layer of the conductor or the coil conductor 6 connected to the hole (via) V reaching the capacitor electrodes 41 and 42 is formed. For example, a Cu film having a thickness of 1 μm or more is formed, and Ti and TiN having a thickness of, for example, 10 nm to 100 nm are formed on the surface of the Cu film. In addition, an adhesion layer may be formed between the Cu film or the Al film and the insulator layer 4. The conductor or the coil conductor 6 is formed by semi-additive plating (SAP), lift-off, wet etching, or the like.

As shown in step (9), the insulator layer 5A such as an organic insulating film is formed over the entire region of the conductor electrically connected to the capacitor electrodes 41 and 42 and the upper portion of the first layer of the coil conductor 6, and a hole (via) V electrically connected to the capacitor electrode 41 is formed.

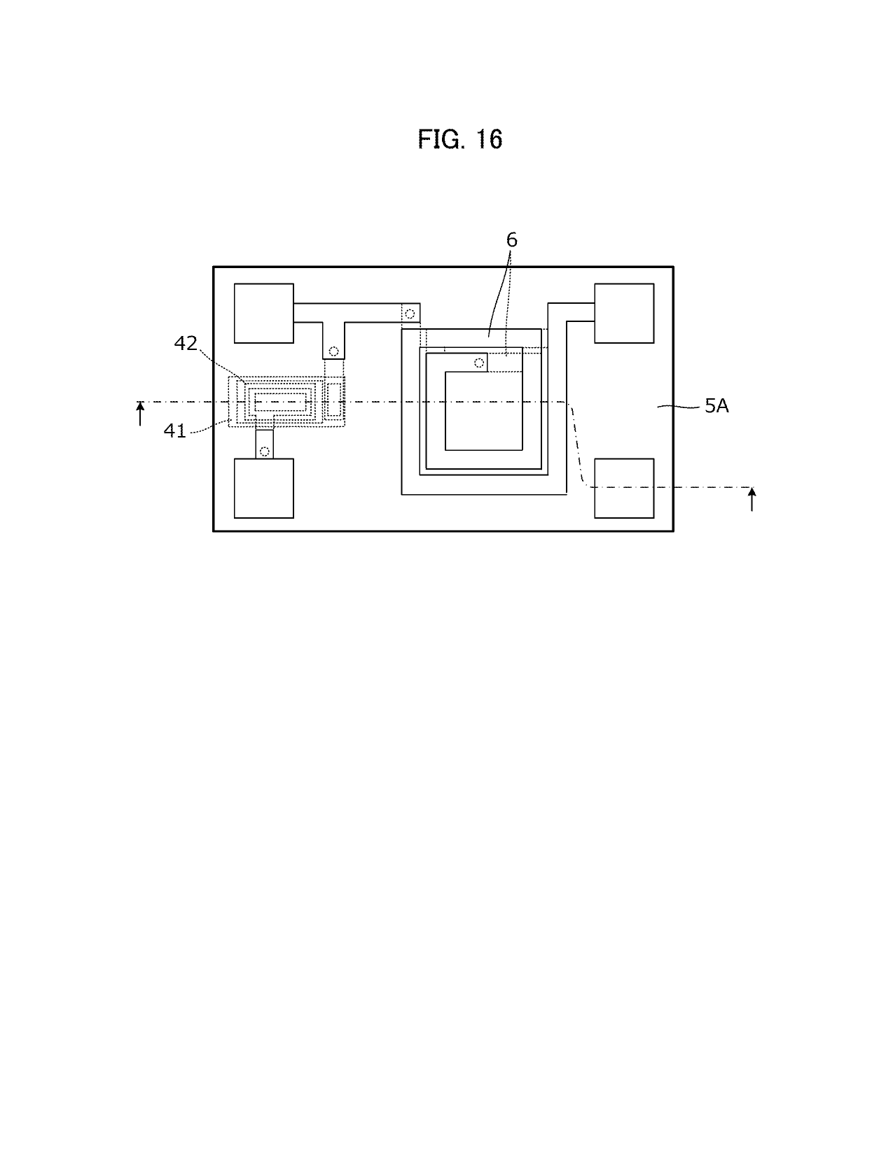

As shown in step (10), a second layer of the conductor or the coil conductor 6 electrically connected to the capacitor electrodes 41 and 42 is formed in the same manner as the first layer. FIG. 16 is a plan view in this state.

As shown in step (11), the insulator layer 5B such as an organic insulating film is formed on the entire region of the conductor electrically connected to the capacitor electrodes 41 and 42 and the upper portion of the second layer of the coil conductor 6 to form a hole (via) V for electrically connecting the chip component side mounting electrode.

As shown in step (12), the chip component side mounting electrodes 7A and 7B are formed by soldering or the like in the holes (vias), and each chip is separated from the wafer.

Thereafter, the chip component 105 is mounted on a circuit board, and the insulator layer 4 is brought into an open state in which the element substrate 1 is absent, for example, in the same manner as the process illustrated in FIG. 3.

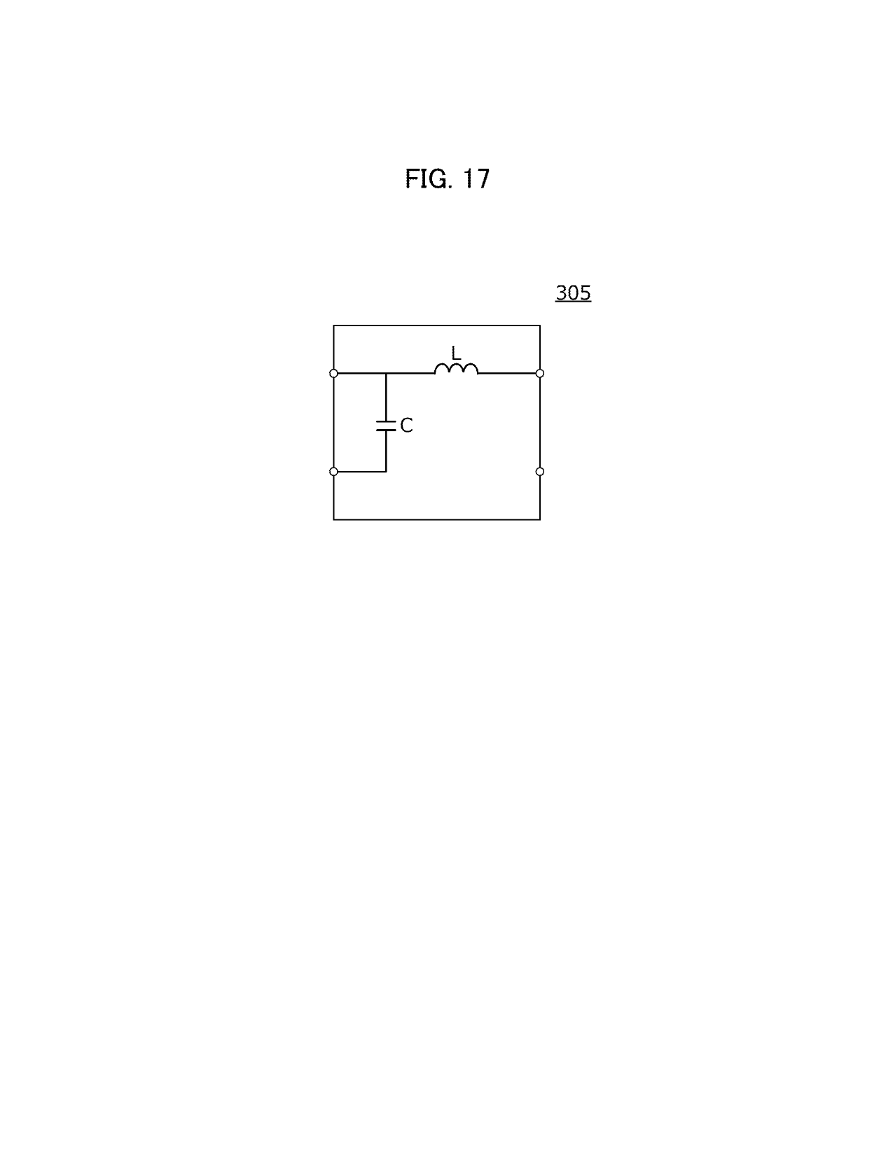

FIG. 17 is a circuit diagram of a circuit configured at a predetermined position on the circuit board by the electronic circuit device 305 according to the present embodiment. This example is a circuit in which the ends of the inductor L and the capacitor C are connected to each other. According to the exemplary aspect, the chip component 105 can be configured as an element in which the inductor L and the capacitor C are connected in series or an element in which the inductor L and the capacitor C are connected in parallel.

Finally, it is noted that the present invention is not limited to the above-described embodiments. Modifications and changes can be appropriately made by those skilled in the art.

For example, in each embodiment, the example in which the coating height of the coating resin 10 with respect to the circuit board 201 is higher than the height of the chip component has been described, but the coating height of the coating resin 10 with respect to the circuit board 201 may be substantially the same as the upper surface of the chip component. Even in this case, when the element substrate 1 of the chip component is ground to expose the insulator layer in a state where the chip component is mounted on the circuit board 201, stress on the chip component can be suppressed.

In the above description, the coil conductor 6 is configured to generate the magnetic flux, and the generation of the eddy current by the magnetic flux has been described. However, when the coil by the coil conductor receives the magnetic flux component in the direction perpendicular to the insulator layer, the generation of the eddy current by the magnetic flux can be similarly suppressed.

In addition, in the first embodiment, the example in which the entire coil opening exists in the region formed by the insulator exposed portion 4S when viewed in the stacking direction of the element substrate 1 and the insulator layers 5A and 5B has been described, but the effect of suppressing the eddy current by the Si substrate is generated even if at least a part of the coil opening by the coil conductor exists in the insulator exposed region when viewed in the stacking direction.

In addition, in the second embodiment, the example in which the entire coil opening is within the formation region of the insulator exposed portion when viewed in the stacking direction of the element substrate 1 and the insulator layers 5A and 5B has been described. However, even when at least a part of the coil opening formed by the coil conductor is within the formation region of the insulator exposed portion when viewed in the stacking direction, the effect of suppressing the eddy current by the Si substrate is generated.

In addition, although the vicinity of a single chip component is illustrated in FIGS. 3, 6(a), 6(b), 8, 11, and the like, a plurality of chip components can be mounted on a circuit board, and these chip components can be ground simultaneously.

In the fifth embodiment, the capacitor is shown as an example of the circuit element other than the coil conductor at the position where the element substrate 1 exists as viewed in the stacking direction of the element substrate 1 and the insulator layer, but other elements may be formed.

In addition, a diode, a transistor, or a MOS capacitor using a part of the element substrate 1 may be formed as a circuit element other than the coil conductor.

What is claimed:

1. An electronic circuit device comprising:
a circuit board;
a coating resin; and
a chip component that includes:
an element substrate having a first main surface and a second main surface that oppose each other;
an insulator layer on a side of the first main surface of the element substrate;
a coil conductor disposed inside the insulator layer and configured to generate or receive a magnetic flux having a vertical component of the first main surface of the element substrate; and
a chip component side mounting electrode on the first main surface side and connecting the coil conductor or a circuit including the coil conductor to the circuit board,
wherein the circuit board has a circuit board side electrode that is connected to the chip component side mounting electrode,
wherein the chip component side mounting electrode is connected to the circuit board side electrode,
wherein the coating resin covers a mounting surface of the circuit board on which the chip component is mounted,
wherein the electronic circuit device further includes an insulator exposed portion in which the insulator layer surrounded by the element substrate is exposed,
wherein a surface that includes the second main surface, the insulator exposed portion, and the coating resin of the element substrate forms a continuous surface, and
wherein at least a part of a coil opening formed by the coil conductor is in a formation region of the insulator exposed portion when viewed in a direction perpendicular to the second main surface of the element substrate.

2. The electronic circuit device according to claim 1, wherein the insulator exposed portion has an area of the second main surface that is smaller than an area of the first main surface of the element substrate.

3. The electronic circuit device according to claim 1, wherein a circuit element other than the coil conductor is disposed at a position where the element substrate exists when viewed in the direction perpendicular to the second main surface.

4. The electronic circuit device according to claim 1, wherein the element substrate is a semiconductor substrate.

5. The electronic circuit device according to claim 1, further comprising a sheath protective resin that coats a surface of the circuit board on which the chip component is mounted.

6. The electronic circuit device according to claim 1, further comprising an in-groove insulator exposed on the first main surface of the element substrate.

7. The electronic circuit device according to claim 6, wherein the in-groove insulator comprises polysilicon.

8. The electronic circuit device according to claim 6, wherein the in-groove insulator comprises a plurality of in-groove insulators that extend horizontally on the first main surface of the element substrate.

9. The electronic circuit device according to claim 6, wherein the in-groove insulator comprises a plurality of in-groove insulators that extend vertically in the first main surface of the element substrate.

10. The electronic circuit device according to claim 6, wherein the in-groove insulator comprises a vertical lattice shape on the first main surface of the element substrate.

11. The electronic circuit device according to claim 6, wherein the in-groove insulator comprises a plurality of portions extending in a longitudinal direction and a portion continuing the portions in a lateral direction on the first main surface of the element substrate.

12. A method for manufacturing an electronic circuit device, the method comprising:
forming a chip component by:
forming a recess on a side of a first main surface of an element substrate having the first main surface and a second main surface that are opposite to each other,
forming an insulator inside the recess,
forming an insulator layer on the side of the first main surface of the element substrate,
forming a coil conductor that is configured to generate or receive a magnetic flux having a vertical component with respect to the insulator layer on the insulator layer, and
forming a chip component side mounting electrode that connects the coil conductor or a circuit including the coil conductor on a circuit board;
forming a circuit board side electrode to which the chip component side mounting electrode is connected on the circuit board;
connecting the chip component side mounting electrode to the circuit board side electrode;
coating a mounting surface of the chip component on the circuit board with a coating resin; and
grinding the element substrate and the insulator layer from the second main surface side until the insulator inside the recess is exposed from the element substrate to form a continuous surface on a surface that includes the second main surface of the element substrate, the insulator inside the recess, and the coating resin.

13. The method according to claim 12, further comprising forming a portion of the insulator that is exposed to have an area of the second main surface that is smaller than an area of the first main surface of the element substrate.

14. The method according to claim 12, further comprising providing a circuit element other than the coil conductor at a position where the element substrate exists when viewed in a direction perpendicular to the second main surface.

15. The method according to claim 12, further comprising forming a sheath protective resin that coats a surface of the circuit board on which the chip component is mounted.

16. The method according to claim 12, further comprising forming an in-groove insulator exposed on the first main surface of the element substrate.

17. The method according to claim 16, further comprising forming the in-groove insulator to include a plurality of in-groove insulators that extend horizontally on the first main surface of the element substrate.

18. The method according to claim 16, further comprising forming the in-groove insulator to include a plurality of in-groove insulators that extend vertically in the first main surface of the element substrate.

19. The method according to claim 16, further comprising forming the in-groove insulator to include a vertical lattice shape on the first main surface of the element substrate.

20. The method according to claim 16, further comprising forming the in-groove insulator to include a plurality of portions extending in a longitudinal direction and a portion continuing the portions in a lateral direction on the first main surface of the element substrate.
